(19) United States
(12) Patent Application Publication
(10) Pub. No.: US 2021/0035831 A1
(43) Pub. Date: Feb. 4, 2021

(54) SUBSTRATE POSITION DETECTING METHOD, SUBSTRATE POSITION ADJUSTING METHOD, AND SUBSTRATE POSITION DETECTING APPARATUS

(71) Applicant: Tokyo Electron Limited, Tokyo (JP)

(72) Inventors: Toshiyuki ARAKANE, Kurokawa-gun (JP); Noriiki MASUDA, Kurokawa-gun (JP); Masanori SATO, Kurokawa-gun (JP)

(21) Appl. No.: 16/945,248

(22) Filed: Jul. 31, 2020

(30) Foreign Application Priority Data
Aug. 2, 2019 (JP) 2019-142674

(51) Int. Cl. H01L 21/67; H01L 21/683; H01L 21/687

(52) U.S. Cl. CPC H01L 21/67259; H01L 21/68707; H01L 21/6831

(57) ABSTRACT

A substrate position detecting method, includes loading a substrate into a processing chamber such that a clean surface of the substrate faces a mounting surface of a stage provided in the processing chamber, mounting the loaded substrate on the stage, fixing the substrate to the stage, releasing the fixing of the substrate to the stage, unloading the substrate out of the processing chamber, detecting a particle distribution of particles on the clean surface of the unloaded substrate, and calculating a positional relationship between the substrate and the stage when the substrate is mounted on the stage, based on the detected particle distribution. The particles include irregularities formed at the time of contact between the clean surface of the substrate and the mounting surface.

### CROSS-REFERENCE TO RELATED APPLICATION

This application is based upon and claims the benefit of priority from Japanese Patent Application No. 2019-142674, filed on Aug. 2, 2019, the entire contents of which are incorporated herein by reference.

### TECHNICAL FIELD

The present disclosure relates to a substrate position detecting method, a substrate position adjusting method, and a substrate position detecting apparatus.

### BACKGROUND

The position of a semiconductor wafer (hereinafter referred to as wafer) may be deviated in a process module due to the time-dependent change of components such as an electrostatic chuck and the like arranged in a substrate processing apparatus. Thus, a position detector that measures a position of a wafer before loading the wafer into a process module and after unloading the wafer from the process module has been proposed. The position detector detects a positional deviation amount based on the measured position. Then, the position detector corrects the position of the wafer based on the detected positional deviation amount and transfers the wafer to the next process module.

Further, there has been proposed a technique in which all the wafers are not allowed to pass through a position detector and the transfer of substrates to the position detector is suppressed to improve the throughput (Patent Document 1).

### PRIOR ART DOCUMENT

### Patent Document

(Patent Document 1) Japanese Patent Application Publication No. 2016-122775

### SUMMARY

According to one embodiment of the present disclosure, there is provided a substrate position detecting method, including: loading a substrate into a processing chamber such that a clean surface of the substrate faces a mounting surface of a stage provided in the processing chamber; mounting the loaded substrate on the stage; fixing the substrate to the stage; releasing the fixing of the substrate to the stage; unloading the substrate out of the processing chamber; detecting a particle distribution of particles on the clean surface of the unloaded substrate; and calculating a positional relationship between the substrate and the stage when the substrate is mounted on the stage, based on the detected particle distribution, wherein the particles include irregularities formed at the time of contact between the clean surface of the substrate and the mounting surface.

### BRIEF DESCRIPTION OF DRAWINGS

The accompanying drawings, which are incorporated in and constitute a part of the specification, illustrate embodiments of the present disclosure, and together with the general description given above and the detailed description of the embodiments given below, serve to explain the principles of the present disclosure.

FIG. 1 is a diagram showing an example of a configuration of a substrate position detecting apparatus according to an embodiment.

FIG. 2 is a diagram showing a schematic configuration of a substrate processing apparatus according to an embodiment.

FIG. 3A is a diagram showing an example of a particle distribution on a wafer.

FIG. 3B is an enlarged view of portion 1 in FIG. 3A.

FIG. 3C is an enlarged view of portion 2 in FIG. 3A.

FIG. 4 is a diagram for explaining a positional relationship when a wafer is mounted on a stage of a substrate processing apparatus.

FIG. 5 is a diagram showing an example of a configuration of a particle distribution stored in a distribution storage part.

FIG. 6 is a diagram showing an example of a configuration of a deviation amount stored in a deviation amount storage part.

FIG. 7 is a diagram illustrating an example of a configuration of an adjustment process stored in an adjustment storage part.

FIG. 8 is a flowchart showing an example of a flow of a substrate position detecting process according to an embodiment.

FIG. 9 is a flowchart showing an example of a flow of a detecting process according to an embodiment.

FIG. 10 is a flowchart illustrating an example of a flow of an adjusting process according to an embodiment.

FIG. 11 is a diagram for explaining the accuracy of a deviation amount calculated by a substrate position detecting apparatus according to an embodiment.

FIG. 12 is a diagram for explaining an example of a computer that executes a substrate position detecting process according to an embodiment.

FIG. 13 is a diagram for explaining an example of a method of detecting a positional deviation of a wafer.

FIGS. 14A and 14B are diagrams for explaining a relative positional relationship between a wafer and a stage when the wafer is mounted on the stage.

### DETAILED DESCRIPTION

Reference will now be made in detail to various embodiments, examples of which are illustrated in the accompanying drawings. In the following detailed description, numerous specific details are set forth in order to provide a thorough understanding of the present disclosure. However, it will be apparent to one of ordinary skill in the art that the present disclosure may be practiced without these specific details. In other instances, well-known methods, procedures, systems, and components have not been described in detail so as not to unnecessarily obscure aspects of the various embodiments.

Hereinafter, the disclosed embodiments will be described in detail with reference to the drawings. The present embodiments are not limiting. Further, the respective embodiments may be appropriately combined. Moreover, in the subject specification and the drawings, substantially the same components are denoted by like reference numerals, and the duplicate description thereof will be omitted.

As mentioned earlier, when the wafer position is measured before loading the wafer into the process module and after unloading the wafer from the process module, it is impossible to detect the accurate position of the wafer when the wafer is mounted on the stage in the process module.

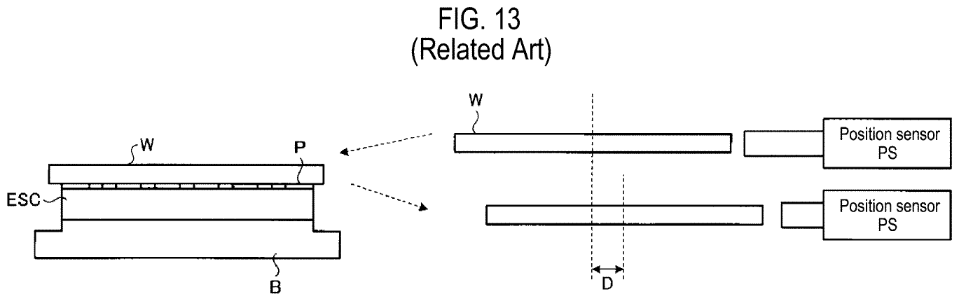

FIG. 13 is a diagram for explaining an exemplary method of detecting a positional deviation of a wafer. The left side in FIG. 13 shows a state in which a wafer W is mounted on a stage in a process module. The stage includes a support part B and an electrostatic chuck ESC. The electrostatic chuck ESC is supported on the support part B. A protrusion P that supports the wafer W is formed on the electrostatic chuck ESC. When a voltage is applied to the electrostatic chuck ESC to generate an electrostatic force, the lower surface of the wafer W is attracted to the upper surface of the protrusion P. The wafer W passes through a transfer chamber arranged on the process module loading/unloading port side before being loaded into the process module. A position sensor PS is arranged in the transfer chamber so as to sandwich the wafer W passing through a transfer route on, for example, the left and right sides of the transfer route. FIG. 13 shows one position sensor PS as an example. The position sensor PS detects the position of the wafer W before loading the wafer W into the process module and after unloading the wafer W from the process module. For example, the transfer position of the wafer W may be deviated before and after being loaded into the process module as shown on the right side in FIG. 13. In FIG. 13, the position sensor PS detects the positional deviation D before and after loading the wafer W in one direction.

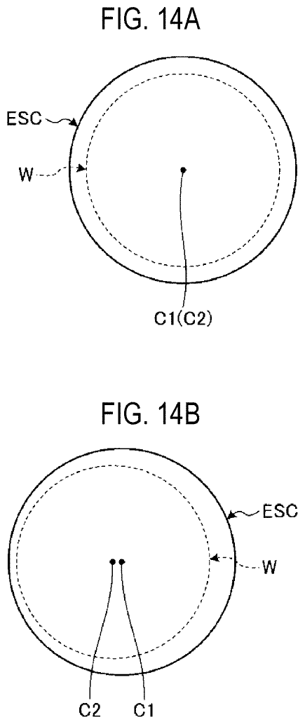

However, when the positional deviation D of the wafer W before and after loading the wafer W is detected as in FIG. 13, the position of the wafer W in the process module is unknown. FIGS. 14A and 14B are diagrams showing a relative positional relationship between the wafer W and the stage when the wafer W is mounted on the stage. In FIGS. 14A and 14B, the outer circumference of the stage is indicated by a solid line, and the outer circumference of the wafer W is indicated by a dotted line. FIG. 14A shows a state in which the center C1 of the stage (i.e., the center of the electrostatic chuck ESC) and the center C2 of the wafer W coincide with each other. On the other hand, FIG. 14B shows a state in which the center C1 of the stage and the center C2 of the wafer W are deviated from each other. When a positional deviation before and after loading the wafer W is generated as shown in FIG. 13, the wafer W in the process module may be in the state as shown in FIG. 14A or may be in the state as shown in FIG. 14B. As described above, the position sensor PS shown in FIG. 13 cannot detect the deviation of the arrangement position of the wafer W on the stage shown in FIG. 14B.

The substrate position detecting method and the substrate position detecting apparatus according to the present disclosure provide a technique capable of detecting the position of a wafer when the wafer is mounted on a stage.

### (Example of Configuration of Substrate Position Detecting Apparatus)

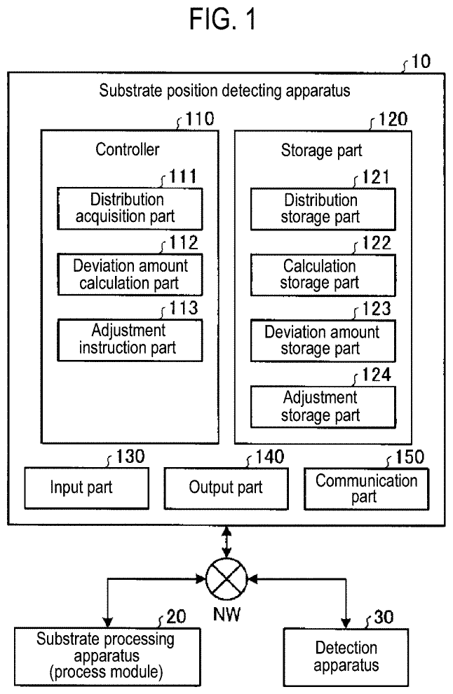

FIG. 1 is a diagram showing an example of a configuration of a substrate position detecting apparatus 10 according to an embodiment. The substrate position detecting apparatus 10 of FIG. 1 may be configured by an information processing device such as, for example, a personal computer (PC) or the like. The substrate position detecting apparatus 10 is communicatively connected to a substrate processing apparatus 20 and a detection apparatus 30 via a network NW.

The network NW may be, for example, the Internet, an intranet, a local area network, a wide area network or a combination thereof. Further, the network 50 may be a wired network, a wireless network or a combination thereof.

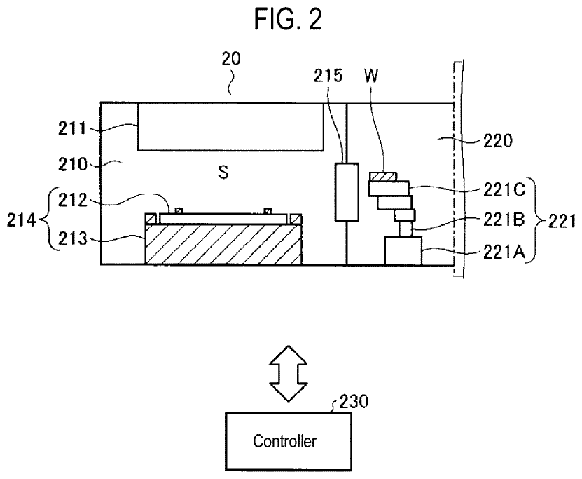

The substrate processing apparatus 20 has a space in which a process for a wafer is executed, and executes the process for the wafer. The substrate processing apparatus 20 corresponds to the above-described process module. FIG. 2 is a diagram showing a schematic configuration of the substrate processing apparatus 20 according to the embodiment. The substrate processing apparatus 20 shown in FIG. 2 includes a processing chamber 210, a transfer chamber 220 and a controller 230.

The configuration and type of the substrate processing apparatus 20 are not particularly limited. The substrate processing apparatus 20 may be, for example, a plasma processing apparatus that makes use of an arbitrary plasma source such as capacitively coupled plasma (CCP), inductively coupled plasma (ICP), or microwave plasma. The substrate processing apparatus 20 executes a film-forming process such as atomic layer deposition (ALD), chemical vapor deposition (CVD) or the like, an etching processing, etc. The substrate processing apparatus 20 may be an apparatus that makes use of plasma in processing a wafer, or an apparatus that does not make use of plasma.

The processing chamber 210 constitutes a processing space S in which a process for a wafer W is performed. An upper electrode 211 is arranged on the upper side of the processing chamber 210. A stage 214 including an electrostatic chuck 212 and a support part 213 as a structure for supporting the electrostatic chuck 212 from below is arranged on the lower side of the processing chamber 210. The electrostatic chuck 212 attracts and holds the wafer W by, for example, an electrostatic force. The upper surface of the electrostatic chuck 212, i.e., the mounting surface on which the wafer W is mounted, has a substantially circular shape. On the electrostatic chuck 212, a ring-shaped convex portion (a seal band SB described later) that supports the wafer W is formed. Although not shown, the processing chamber 210 is provided with a power source for applying a voltage to the upper electrode 211 and the electrostatic chuck 212, a supply mechanism for supplying a processing gas to the processing chamber 210, an exhaust mechanism for evacuating the processing space S, a temperature control mechanism for controlling the temperature of the stage, and the like. When the wafer is processed, the processing space S in the processing chamber 210 is depressurized to a vacuum atmosphere. A gate 215 is provided on one wall of the processing chamber 210. The processing space S of the processing chamber 210 communicates with the transfer chamber 220 via a gate 215. Further, the wafer is loaded into the processing chamber 210 from the transfer chamber 220 via the gate 215 and is unloaded from the processing chamber 210 to the transfer chamber 220 via the gate 215.

The transfer chamber 220 constitutes a transfer space for transferring the wafer W and consumable components into the processing chamber 210. Although not shown, the transfer chamber 220 includes an exhaust mechanism for depressurizing the transfer space to a vacuum atmosphere.

A transfer mechanism 221 is arranged in the transfer chamber 220. The transfer mechanism 221 includes a support portion 221A and an arm 221C connected to the support portion 221A via a shaft 221B. In the example of FIG. 2, the support portion 221A is fixed to the bottom surface of the transfer chamber 220. The arm 221C is, for example, a multi-joint robot arm capable of moving in three axis (X, Y and Z) directions. A grip portion capable of gripping the wafer W is provided at the distal end of the arm 221C. The grip portion holds the wafer W on the flat plate-shaped distal end portion. By moving the arm 221C, the wafer W on the grip portion is loaded into the processing chamber 210 and mounted on the electrostatic chuck 212. In addition, the arm 221C unloads the wafer W to the outside of the processing chamber 210 from above the electrostatic chuck 212.

The controller 230 is an information processing device that controls the process executed in the processing chamber 210 and the operation of the transfer mechanism 221. The controller 230 may include, for example, various integrated circuits and electronic circuits. The controller 230 may include, for example, a CPU (Central Processing Unit), an MPU (Micro Processing Unit), or the like. The controller 230 also includes a non-transitory memory part that stores information for controlling the process executed in the processing chamber 210 and the operation of the transfer mechanism 221. The memory part may include, for example, a VRAM (Video Random Access Memory), a RAM (Random Access Memory), a ROM (Read Only Memory), and the like.

In the example of FIG. 1, the substrate position detecting apparatus 10 and the substrate processing apparatus 20 are described as separate apparatuses. However, the function of the controller 230 may be configured as a part of the function of the substrate position detecting apparatus 10.

The detection apparatus 30 is an apparatus that detects a particle distribution on the wafer W. The detection apparatus 30 detects irregularities on the wafer W, particles adhering to the wafer W, and the like. The particle distribution is information indicating a distribution of irregularities on the wafer W, particles adhering to the wafer W, and the like. The particle distribution is, for example, image information detected from the wafer W by the detection apparatus 30. The specific configuration of the detection apparatus 30 is not particularly limited. The detection apparatus 30 includes, for example, a light source and a sensor that detects reflected light generated by the light emitted from the light source and reflected by the wafer. The detection apparatus 30 detects irregularities on the wafer W, particles adhering to the wafer W, and the like, based on the output of the sensor.

In FIG. 1, the detection apparatus 30 will be described as an apparatus separate from the substrate position detecting apparatus 10 and the substrate processing apparatus 20. However, the detection apparatus 30 may be configured integrally with the substrate position detecting apparatus 10 or the substrate processing apparatus 20. Further, the substrate position detecting apparatus 10, the substrate processing apparatus 20 and the detection apparatus 30 may be integrally formed. In this case, there may be provided a controller that controls the substrate position detecting apparatus 10, the substrate processing apparatus 20 and the detection apparatus 30 as a whole.

Returning back to FIG. 1, the description of the substrate position detecting apparatus 10 will continue. The substrate position detecting apparatus 10 includes a controller 110, a storage part 120, an input part 130, an output part 140, and a communication part 150.

The controller 110 controls the operation and function of the substrate position detecting apparatus 10. The controller 110 is, for example, an integrated circuit or an electronic circuit. The controller 110 includes, for example, a CPU (Central Processing Unit), an MPU (Micro Processing Unit), and the like.

The storage part 120 stores information used for processing in the substrate position detecting apparatus 10 and information generated as a result of the processing. The storage part 120 includes, for example, a flash memory, a RAM (Random Access Memory), a ROM (Read Only Memory), a hard disk, an optical storage device, and the like.

The input part 130 receives information input to the substrate position detecting apparatus 10 from the outside. The input part 130 includes, for example, a touch panel, a mouse, a keyboard, a microphone, and their peripheral circuits.

The output part 140 outputs information from the substrate position detecting apparatus 10. The output part 140 includes, for example, a screen, a speaker, a printer, and their peripheral circuits.

The communication part 150 realizes communication with other apparatuses via the network NW. The communication part 150 includes, for example, a modem, a port, a router and a switch.

### (Configuration and Function of Controller 110)

The controller 110 includes a distribution acquisition part 111, a deviation amount calculation part 112, and an adjustment instruction part 113.

The distribution acquisition part 111 acquires a particle distribution on the wafer W, which is detected by the detection apparatus 30, from the detection apparatus 30 via the network NW and the communication part 150.

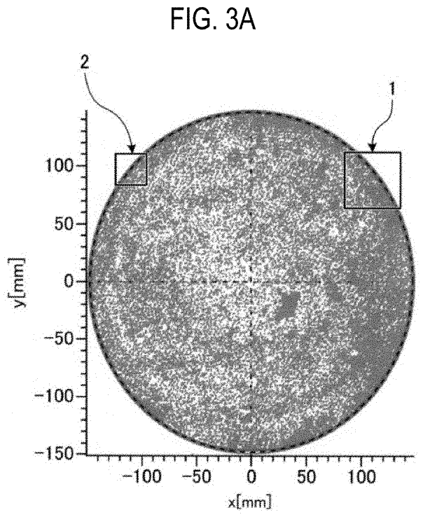

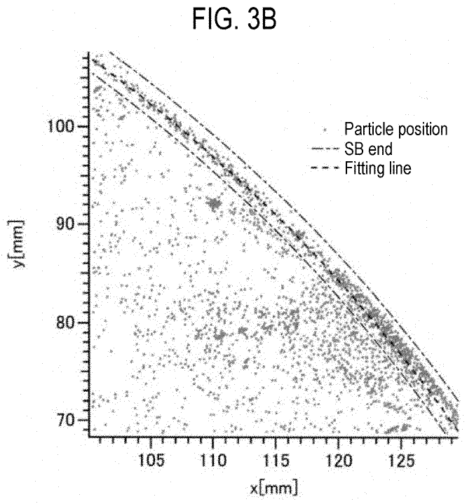

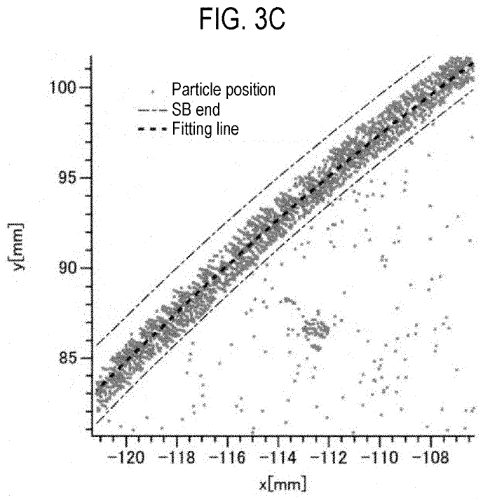

FIG. 3A is a diagram showing an example of a particle distribution on the wafer W. The example of FIG. 3A shows a particle distribution detected from the wafer W having a diameter of 300 mm. The particle distribution of FIG. 3A was detected by the detection apparatus 30 after the wafer W is mounted on the electrostatic chuck 212 of the substrate processing apparatus 20, attracted to the electrostatic chuck 212 with an electrostatic force generated by applying a voltage to the electrostatic chuck 212, detached from the electrostatic chuck 212 and unloaded from the substrate processing apparatus 20. As can be seen from FIG. 3A, irregularities generated when making contact with the electrostatic chuck 212 and particles adhering to the wafer W are detected from the entire surface of the wafer W that makes contact with the electrostatic chuck 212.

FIG. 3B is an enlarged view of portion 1 in FIG. 3A. The portion 1 is near the edge of the wafer W. As can be seen from FIG. 3B, there is a portion near the edge of the wafer W where the particle distribution increases in a substantially arc shape. In FIG. 3B, the position where the particle distribution increases is indicated by a dotted line (in FIG. 3B, a “fitting line”).

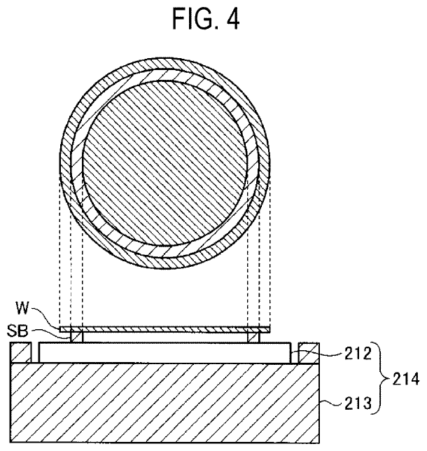

The reason why the particle distribution increases in an arc shape near the edge of the wafer W as shown in FIG. 3B will be described with reference to FIG. 4.

FIG. 4 is a diagram for explaining the positional relationship when the wafer W is mounted on the stage 214 of the substrate processing apparatus 20. As shown in FIG. 4, an annular protrusion (hereinafter also referred to as seal band SB) is provided on the electrostatic chuck 212. The seal band SB supports the wafer W. Therefore, a space corresponding to the height of the seal band SB is formed on the back surface of the wafer W. When a voltage is applied to the electrostatic chuck 212 and the wafer W is attracted to the electrostatic chuck 212, the wafer W is attracted to the upper surface of the seal band SB. Thus, at a position corresponding to the seal band SB on the surface of the wafer W, particles or foreign substances adhere to the wafer W, and fine irregularities are generated on the wafer W as the wafer W is pressed against the seal band SB. The seal band SB is formed in a substantially circular shape with the center of the electrostatic chuck 212 used as an origin. The size of the seal band SB is not particularly limited. The seal band SB may have an inner circumference diameter of 290 mm and an outer circumference diameter of 300 mm. The width of the seal band SB is at least 0.01 mm, preferably 1 mm to 5 mm.

Therefore, as shown in FIG. 3B, the number of particles increases at the position corresponding to the seal band SB near the edge of the wafer W. The one-dot chain line in FIG. 3B indicates the position where the seal band SB is supposed to be located due to the design of the substrate processing apparatus 20. That is, the one-dot chain line indicates the position of the seal band SB when the wafer W is arranged on the stage 214 in a state in which the center of the wafer W and the center of the stage 214 coincide with each other.

FIG. 3C is an enlarged view of portion 2 in FIG. 3A. Also in the portion 2 shown in FIG. 3C, as in the portion 1, particles increase in an arc shape. However, the density of particles in the portion 2 is higher than that in the portion 1. It is difficult to visually determine, from the images of FIGS. 3B and 3C, the position where the seal band SB actually makes contact with the wafer W. Further, as shown in FIG. 3B and FIG. 3C, the radial center of the position where the seal band SB is supposed to be located in the design (the position sandwiched by the one-dot chain lines) and the position where the amount of particles is large (the fitting line) are slightly deviated from each other.

Returning back to FIG. 1, the description of the controller 110 will continue. The controller 110 further includes a deviation amount calculation part 112. The deviation amount calculation part 112 calculates a deviation amount between the center of the wafer W and the center of the seal band SB (i.e., the center of the stage 214) based on the particle distribution acquired by the distribution acquisition part 111.

The deviation amount calculation part 112 calculates a deviation amount by executing regression calculation based on the following equation (1).

(x−a)²+(y−b)²=r² (1)

Equation (1) described a circle. In equation (1), a represents the x coordinate of the center of a circle, b represents the y coordinate of the center of a circle, and r represents the radius of a regression circle. The coordinates (x, y) are the coordinates of an arbitrary point on a circumference. If a, b and r are obtained by using equation (1) as a regression equation and setting variables to x and y, it is possible to obtain a deviation amount of the center of the seal band SB, i.e., the center of the stage 214, with respect to the center of the wafer W 1. The deviation amount calculation part 112 extracts a particle distribution within the supposed position of the seal band SB shown in FIGS. 3B and 3C (between the one-dot chain lines in FIGS. 3B and 3C), and then calculates a, b and r by the regression calculation (least squares method) based on equation (1). The deviation amount calculation part 112 calculates, for example, a and b as the deviation amounts from the wafer center, respectively. Further, the deviation amount calculation part 112 calculates, for example, r as the diameter of a circle passing through the width center of the seal band SB.

The adjustment instruction part 113 gives an instruction to execute an adjustment process based on the deviation amount calculated by the deviation amount calculation part 112. The adjustment process is, for example, adjustment of a position of a transfer route of the wafer W by the transfer mechanism 221. Further, the adjustment process is, for example, reassembling of the substrate processing apparatus 20. The adjustment instruction part 113 transmits an instruction to the controller 230 of the substrate processing apparatus 20 according to the preset content of the adjustment process. In addition, the adjustment instruction part 113 outputs an alert to the output part 140 according to the preset content of the adjustment process.

### (Information Stored in Storage Part 120)

The storage part 120 includes a distribution storage part 121, a calculation storage part 122, a deviation amount storage part 123, and an adjustment storage part 124.

The distribution storage part 121 stores the particle distribution acquired by the distribution acquisition part 111. For example, the distribution storage part 121 stores the particle distribution detected from the wafer W processed by the substrate processing apparatus 20 in association with the substrate processing apparatus 20.

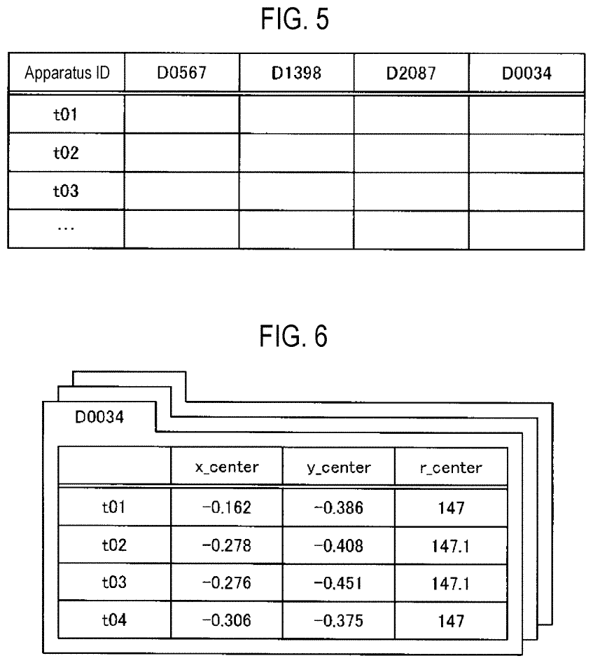

FIG. 5 is a diagram showing an example of the configuration of the particle distribution stored in the distribution storage part 121. In the example of FIG. 5, the particle distribution includes an apparatus ID, timing information, and a distribution map. The apparatus ID is an identifier that uniquely identifies each substrate processing apparatus 20. The timing information indicates the timing at which the distribution acquisition part 111 acquires a distribution map. The timing information is, for example, the date and time when the distribution map is detected from the wafer W. The distribution map is an image of the actual particle distribution shown in FIGS. 3A to 3C or data obtained by binarizing the image.

In the example of FIG. 5, distribution maps of timings “t01”, “t02” and “t03” are stored in association with “apparatus ID, D0567”. This indicates that the distribution maps of the wafer W processed by the substrate processing apparatus 20 specified by the apparatus ID “D0567” is acquired and stored at timing “t01” and the like.

The calculation storage part 122 stores the regression calculation equation, variables, parameters, and the like used by the deviation amount calculation part 112 to calculate the deviation amount. The calculation storage part 122 stores, for example, equation (1) described above. The calculation storage part 122 also stores the diameter of the wafer W, the outer and inner diameters of the seal band SB, and the like.

The deviation amount storage part 123 stores the deviation amount calculated by the deviation amount calculation part 112. FIG. 6 is a diagram showing an example of the configuration of the deviation amount stored in the deviation amount storage part 123. In the example of FIG. 6, the calculation results based on the distribution maps acquired at the respective timings are stored in association with the apparatus IDs. For example, “x_center, −0.162”, “y_center, −0.386”, and “r_center, 147” are stored as the calculation results based on the distribution map acquired at timing “t01”. This indicates that in the distribution map acquired at timing “t01”, the calculated x-coordinate of the center of the circle (corresponding to the center of the seal band SB) is deviated by −0.162 mm from the reference coordinate. This also indicates that the y coordinate of the center of the circle is deviated by −0.386 mm from the reference coordinate. In addition, this indicates that the radius of the regression circle was 147 mm.

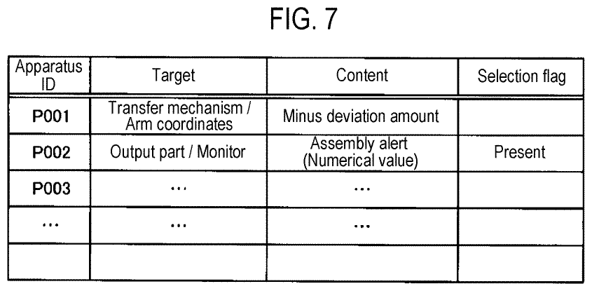

The adjustment storage part 124 stores the content of an adjustment process. The adjustment storage part 124 stores, for example, the content of the process recommended to be executed as a result of the deviation amount calculation. FIG. 7 is a diagram showing an example of the configuration of the adjustment process stored in the adjustment storage part 124. In the example of FIG. 7, “target”, “content” and “selection flag” are stored in association with “process ID”. The “process ID” is an identifier that uniquely identifies the adjustment process. The “target” indicates a structural part as a target of the adjustment process. That is, the “target” indicates a target for which execution of the adjustment process is instructed by the adjustment instruction part 113. The “content” indicates an operation executed as the adjustment process, information to be displayed, and the like. The “selection flag” indicates whether or not the adjustment process of the corresponding process ID is selected. In the example of FIG. 7, “target, transfer mechanism/arm coordinates” and “content, minus deviation amount” are stored in association with “process ID, P001”. This indicates that the coordinates of the arm 221C of the transfer mechanism 221 are adjusted in the adjustment process specified by the process ID “P001”. Further, the content of the adjustment indicates that the reference coordinates of the arm 221C are moved in the opposite direction as much as the deviation amount calculated by the deviation amount calculation part 112. Further, in the example of FIG. 7, “target, output part/monitor”, “content, assembly alert (numerical value)”, and “selection flag, present” are stored in association with “process ID, P002”. This indicates that the output to the monitor included in the output part 140 is executed in the adjustment process specified by the process ID “P002”. Further, in the adjustment process specified by the process ID “P002”, an alert is displayed on the monitor, indicating that there is a defect in assembly and the numerical value of the deviation amount in the alert. At this time point, the adjustment process specified by the process ID “P002” is selected.

The information stored in the calculation storage part 122 and the adjustment storage part 124 may be appropriately input or updated by an operator via the input part 130 or the communication part 150.

### (Example of Flow of Substrate Position Detecting Process)

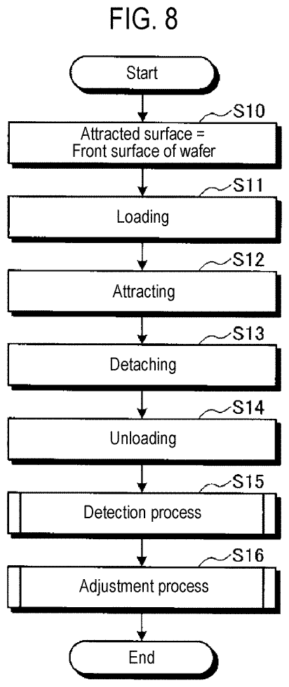

FIG. 8 is a flowchart showing an example of a flow of a substrate position detecting process according to an embodiment. In the substrate position detecting process according to the embodiment, first, the transfer mechanism 221 transfers the wafer W to the processing chamber 210 of the substrate processing apparatus 20. At that time, the wafer W is arranged on the transfer mechanism 221 so that the clean surface among the surfaces of the wafer W, which is polished to form a pattern or the like, faces the electrostatic chuck 212. That is, the wafer W is arranged such that the clean surface (hereinafter also referred to as front surface) of the wafer W serves as an attracted surface facing the electrostatic chuck 212 (step S10). This is because the back side (hereinafter also referred to as back surface) of the clean surface among the surfaces of the wafer W may not be polished in some cases. If the unpolished back surface is attracted to the electrostatic chuck 212, a particle distribution suitable for calculating the deviation amount cannot be obtained because many particles and dirt exist before the attraction. For this reason, the clean polished surface of the wafer W is used as the attracted surface.

The transfer mechanism 221 loads the wafer W into the processing chamber 210 (step S11). Next, under the control of the controller 230, a voltage is applied to the electrostatic chuck 212 to generate an electrostatic force, whereby the wafer W is attracted to the electrostatic chuck 212, i.e., the seal band SB (step S12). Next, the controller 230 stops the voltage application to the electrostatic chuck 212 and detaches the wafer W from the electrostatic chuck 212 (step S13). The transfer mechanism 221 unloads the wafer W having a particle distribution out of the processing chamber 210 (step S14).

Next, the substrate position detecting apparatus 10 executes a detection process (step S15). The detection process is executed by the substrate position detecting apparatus 10 based on the particle distribution detected by the detection apparatus 30. Thereafter, the substrate position detecting apparatus 10 instructs an adjustment process based on the deviation amount detected in the detection process (step S16). Then, the structural part set as the target of the adjustment process executes the adjustment process. Thus, the substrate position detecting process according to the embodiment comes to an end.

### (One Example of Flow of Detection Process)

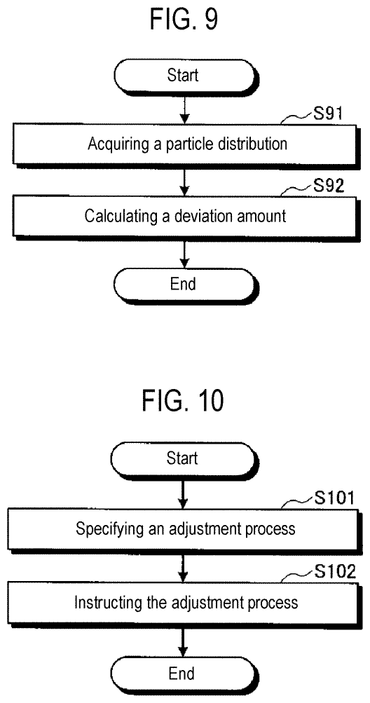

FIG. 9 is a flowchart showing an example of the flow of the detection process according to the embodiment. First, the detection apparatus 30 detects a particle distribution on the wafer W unloaded from the substrate processing apparatus 20. Then, the distribution acquisition part 111 of the substrate position detecting apparatus 10 acquires the particle distribution detected by the detection apparatus 30 (step S91). The acquired particle distribution is appropriately stored in the distribution storage part 121. The deviation amount calculation part 112 calculates a deviation amount based on the particle distribution stored in the distribution storage part 121 and the regression calculation equation, variables, parameters and the like stored in the calculation storage part 122 (step S92). The calculated deviation amount is stored in the deviation amount storage part 123. Thus, the detection process comes to an end.

### (One Example of Flow of Adjustment Process)

FIG. 10 is a flowchart showing an example of the flow of the adjustment process according to the embodiment. First, the adjustment instruction part 113 of the substrate position detecting apparatus 10 specifies a process having a selection flag “present” by referring to the adjustment storage part 124 (step S101). Then, the adjustment instruction part 113 instructs the target of the specified process to execute the content of the specified process (step S102). Thus, the adjustment process comes to an end.

### (Accuracy of Deviation Amount Calculated According to the Embodiment)

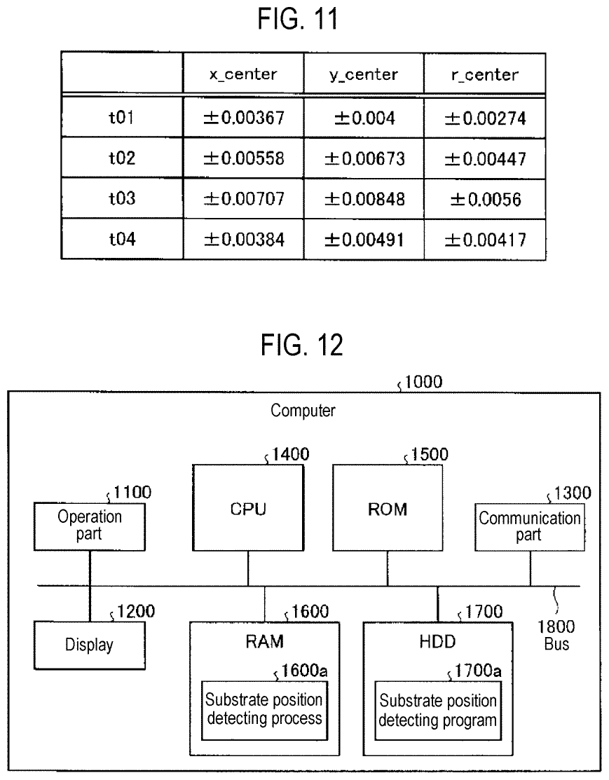

FIG. 11 is a diagram for explaining the accuracy of the deviation amount calculated by the substrate position detecting apparatus 10 according to the embodiment. The numerical values shown in FIG. 11 indicate calculation errors of the respective parameters when a, b and r are calculated using the above-described equation (1). As can be seen from the numerical values shown in FIG. 11, the calculation accuracy when the respective parameters are calculated using the above-described equation (1) is several micrometers. As described above, by using the substrate position detecting method of the present embodiment, the position of the wafer W on the stage (i.e., the relative position of the seal band SB with respect to the wafer W) can be detected with high accuracy.

### Effects of the Embodiment

The substrate position detecting method according to the above-described embodiment includes a step of loading the substrate into the processing chamber such that the clean surface of the substrate faces the mounting surface of the stage provided in the processing chamber. Further, the substrate position detecting method includes a step of mounting the loaded substrate on the stage. Further, the substrate position detecting method includes a step of fixing the substrate to the stage. Further, the substrate position detecting method includes a step of releasing the fixing of the substrate to the stage. Further, the substrate position detecting method includes a step of unloading the substrate out of the processing chamber. Further, the substrate position detecting method includes a step of detecting a particle distribution on the clean surface of the unloaded substrate. Further, the substrate position detecting method includes a step of calculating a positional relationship between the substrate and the stage when the substrate is mounted on the stage, based on the detected particle distribution. The particles include irregularities formed when the clean surface of the substrate makes contact with the mounting surface. Accordingly, the substrate position detecting method according to the embodiment can accurately detect the position of the substrate on the stage.

Further, in the calculating step of the substrate position detecting method according to the above-described embodiment, the position where the protrusion of the mounting surface makes contact with the clean surface is calculated based on the particle distribution. Therefore, according to the embodiment, it is possible to accurately detect the position when the substrate is actually present on the stage.

Further, in the calculating step of the substrate position detecting method according to the above-described embodiment, the position where the substantially circular annular protrusion formed on the mounting surface makes contact with the clean surface may be calculated based on the particle distribution. Therefore, according to the embodiment, it is possible to accurately detect the position when the substrate is actually present on the stage. In addition, according to the embodiment, the relative position of the substrate with respect to the stage is detected by using the shape of the structure arranged on the stage. Accordingly, the processing can be realized without requiring an additional structure.

Further, in the fixing step of the substrate position detecting method according to the above-described embodiment, the substrate may be fixed on the stage by an electrostatic force. Therefore, according to the embodiment, the relative position of the substrate with respect to the stage can be detected by using the structure provided in the substrate processing apparatus.

Further, the substrate position detecting method according to the above-described embodiment may further include a step of adjusting the transfer route of the substrate to the stage based on the calculated positional relationship. Therefore, according to the embodiment, the accuracy of the subsequent processing can be improved pursuant to the detection result.

Further, the substrate position detecting method according to the above-described embodiment may further include a step of displaying an alert based on the calculated positional relationship. Therefore, according to the embodiment, the manager of the substrate processing apparatus can quickly perform the adjustment based on the state of the substrate processing apparatus. For example, the manager can improve the assembling accuracy of the substrate processing apparatus pursuant to the detection result.

The substrate position adjusting method according to the above-described embodiment includes a step of calculating a positional relationship between the substrate and the stage based on the distribution of particles adhering to the surface of the substrate arranged on the mounting surface of the stage. Further, the substrate position adjusting method includes a step of adjusting the relative position between the stage and the substrate based on the calculated positional relationship. For example, the substrate position adjusting method can adjust the position of the transfer route for transferring the substrate. Therefore, according to the embodiment, it is possible to improve the processing accuracy of the substrate pursuant to the detection result.

Further, the substrate position detecting apparatus according to the embodiment includes the storage part and the controller. The controller included in the substrate position detecting apparatus executes the above-described substrate position detecting method or the above-described substrate position adjusting method by executing the instructions stored in the storage part. Therefore, the substrate position detecting apparatus according to the embodiment can accurately detect the relative position of the substrate in the substrate processing apparatus and can perform the processing pursuant to the detection result.

### (Modification)

In the above-described embodiment, the substrate position detecting apparatus is configured to detect the position of the substrate with respect to the stage using the seal band on the stage. The present disclosure is not limited thereto. The substrate position detecting apparatus may be configured to detect the position of the wafer using another structure provided on the stage to make contact with the substrate. Further, in the above-described embodiment, the shape of the seal band is a circle. However, the relative position of the substrate with respect to the stage may be detected based on the position of the seal band having another shape. In addition, a method such as a least squares method or the like may be used for position detection.

Further, in the above-described embodiment, the processing conditions of the substrate may be adjusted by monitoring the machine difference based on the calculated deviation amount. Further, before actually using the substrate processing apparatus, the deviation amount may be calculated using the substrate position detecting method according to the above-described embodiment, and may be used for adjusting the assembly of the substrate processing apparatus. In addition, after the use of the substrate processing apparatus is started, the deviation amount may be periodically detected and fed back to the controller (the controller 230 in FIG. 2) or the like.

In the above-described embodiment, the substrate is fixed by being attracted by the electrostatic chuck with an electrostatic force. However, the present disclosure is not limited thereto. The method of fixing the substrate may be any method. For example, the back surface of the substrate may be attracted and fixed to the electrostatic chuck (seal band) by merely vacuum-drawing the substrate, or the substrate may be fixed by using other means.

The length of the time for which the substrate is attracted to the electrostatic chuck to obtain the particle distribution, the voltage value applied to the electrostatic chuck, and the like are not particularly limited. For example, the substrate may be attracted to the electrostatic chuck by applying a voltage of about 2000 V for several tens of seconds. According to experiments, even if the attraction time is prolonged, the amount of information that can be acquired as the particle distribution (the amount of adhering particles) does not particularly increase. However, the amount of information that can be acquired as the particle distribution is small when the wafer is merely placed on the electrostatic chuck without being attracted to the electrostatic chuck. Therefore, it is desirable to perform the attraction to the electrostatic chuck. Plasma may or may not be generated during the attraction. From the viewpoint of easy acquisition of the particle distribution, the wafer used in the embodiment is preferably a bare silicon wafer on which an oxide film, a nitride film or the like is not formed. The clean surface of the bare silicon wafer may have a degree of cleanliness with, for example, about 100 particles of 1 μm or less. In addition, seasoning (cleaning) may be performed before executing the substrate position detecting process according to the embodiment.

### [Substrate Position Detecting Program]

In addition, the various processes described in the above embodiments may be realized by distributing a program prepared in advance from a computer such as a server or the like to a computer such as a tablet terminal or a notebook computer, and allowing the server and the computer to perform the processes in cooperation with each other. Therefore, in the following description, an example of a computer that executes a substrate position detecting program having the same functions as those of the above-described embodiment will be described with reference to FIG. 12.

FIG. 12 is a diagram for explaining an example of the computer that executes the substrate position detecting process according to the embodiment. As shown in FIG. 12, the computer 1000 includes an operation part 1100, a display 1200, and a communication part 1300. Further, the computer 1000 includes a CPU (Central Processing Unit) 1400, a ROM (Read Only Memory) 1500, a RAM (Random Access Memory) 1600, and an HDD (Hard Disk Drive) 1700. The respective parts 1100 to 1700 are connected to each other via a bus 1800.

As shown in FIG. 12, the HDD 1700 stores in advance a substrate position detecting program 1700a capable of mounting a module that exhibits the same function as that of each of the parts shown in the above-described embodiment. The substrate position detecting program 1700a may be appropriately integrated or separated like the respective constituent elements shown in FIG. 2. That is, as for the data stored in the HDD 1700, all the data does not always have to be stored in the HDD 1700, and only the data necessary for the processing may be stored in the HDD 1700.

Then, the CPU 1400 reads each module of the substrate position detecting program 1700a from the HDD 1700 and deploys it into the RAM 1600. Thus, as shown in FIG. 12, the substrate position detecting program 1700a functions as a substrate position detecting process 1600a. The substrate position detecting process 1600a appropriately deploys various data read from the HDD 1700 into a region allocated to itself on the RAM 1600, and executes various processes based on the various data thus deployed. The substrate position detecting process 1600a includes processes executed by the respective processing parts shown in FIG. 2. As for the respective processing parts virtually realized on the CPU 1400, all the processing parts do not have to operate on the CPU 1400 at all times, and only the necessary processing parts may be virtually realized.

The substrate position detecting program 1700a described above does not necessarily have to be stored in the HDD 1700 or the ROM 1500 from the beginning. For example, each program may be stored in a “portable physical medium” such as a flexible disk or a CD-ROM (Compact Disc Read Only Memory) inserted into the computer 1000. Alternatively, each program may be stored in a “portable physical medium” such as a DVD (Digital Versatile Disc), a magneto-optical disc or an IC card. Then, the computer 1000 may acquire each program from these portable physical media and may execute the same. In addition, each program may be stored in another computer or a server device connected to the computer 1000 via a public line, the Internet, a LAN, a WAN (Wide Area Network), or the like. Then, the computer 1000 may acquire each program from them and may execute the same.

According to some embodiments of the present disclosure, it is possible to detect a position of a substrate on a stage.

While certain embodiments have been described, these embodiments have been presented by way of example only, and are not intended to limit the scope of the disclosures. Indeed, the embodiments described herein may be embodied in a variety of other forms. Further, various omissions, substitutions and changes in the form of the embodiments described herein may be made without departing from the spirit of the disclosures. The accompanying claims and their equivalents are intended to cover such forms or modifications as would fall within the scope and spirit of the disclosures.

What is claimed is:

1. A substrate position detecting method, the method comprising:
loading a substrate into a processing chamber such that a clean surface of the substrate faces a mounting surface of a stage provided in the processing chamber;
mounting the loaded substrate on the stage;
fixing the substrate to the stage;
releasing the fixing of the substrate to the stage;
unloading the substrate out of the processing chamber;
detecting a particle distribution of particles on the clean surface of the unloaded substrate; and
calculating a positional relationship between the substrate and the stage when the substrate is mounted on the stage, based on the detected particle distribution,
wherein the particles include irregularities formed at the time of contact between the clean surface of the substrate and the mounting surface.

2. The method of claim 1, wherein, in the calculating the positional relationship, a position where a protrusion of the mounting surface makes contact with the clean surface is calculated based on the particle distribution.

3. The method of claim 2, wherein, in the fixing the substrate, the substrate is fixed to the stage by an electrostatic force.

4. The method of claim 3, further comprising:
adjusting a transfer route of the substrate to the stage based on the calculated positional relationship.

5. The method of claim 4, further comprising:
displaying an alert based on the calculated positional relationship.

6. The method of claim 1, wherein, in the calculating the positional relationship, a position where a substantially circular annular protrusion formed on the mounting surface makes contact with the clean surface is calculated based on the particle distribution.

7. The method of claim 1, wherein, in the fixing the substrate, the substrate is fixed to the stage by an electrostatic force.

8. The method of claim 1, further comprising:
adjusting a transfer route of the substrate to the stage based on the calculated positional relationship.

9. The method of claim 1, further comprising:
displaying an alert based on the calculated positional relationship.

10. A substrate position adjusting method, the method comprising:
calculating a positional relationship between a substrate and a stage when the substrate is mounted on the stage, based on a distribution of particles adhering to a substrate surface arranged on a mounting surface side of the stage; and
adjusting a relative position of the stage and the substrate, based on the calculated positional relationship.

11. A substrate position detecting apparatus, the apparatus comprising:
a storage part; and
a controller that executes a substrate position detecting method by executing instructions stored in the storage part, wherein the method comprises:
loading a substrate into a processing chamber such that a clean surface of the substrate faces a mounting surface of a stage provided in the processing chamber;
mounting the loaded substrate on the stage;
fixing the substrate to the stage;
releasing the fixing of the substrate to the stage;
unloading the substrate out of the processing chamber;
detecting a particle distribution of particles on the clean surface of the unloaded substrate; and
calculating a positional relationship between the substrate and the stage when the substrate is mounted on the stage, based on the detected particle distribution,
wherein the particles include irregularities formed at the time of contact between the clean surface of the substrate and the mounting surface.
